(19) United States
(12) Patent Application Publication
(10) Pub. No.: US 2022/0037574 A1
(43) Pub. Date: Feb. 3, 2022

(54) THERMOELECTRIC DEVICE

(71) Applicant: Sumitomo Chemical Company Limited, Tokyo (JP)

(72) Inventors: Thomas Fletcher, Godmanchester (GB); Simon King, Godmanchester (GB)

(73) Assignee: Sumitomo Chemical Company Limited, Tokyo (JP)

(21) Appl. No.: 17/277,677

(22) PCT Filed: Sep. 17, 2019
(86) PCT No.: PCT/GB2019/052602

§ 371 Date: Mar. 18, 2021

(30) Foreign Application Priority Data
Sep. 19, 2018 (GB) 1815235.5

(51) Int. Cl. H01L 35/26; H01L 35/34; H01L 35/32; H01L 35/16

(52) U.S. Cl. CPC H01L 35/26; H01L 35/16; H01L 35/32; H01L 35/34

(57) ABSTRACT

A thermoelectric device includes each an n-type thermoelectric leg and a p-type thermoelectric leg electrically coupled by an electrical contact. At least one of the n-type and p-type thermoelectric legs contains a particulate semiconductor mixed with hollow microspheres. The hollow microspheres may make up between 40% and 90% by volume of the thermoelectric leg. Adjacent thermoelectric couples may be electrically coupled by a second electrical contact. The thermoelectric legs may be printed by deposition of an ink.

### BACKGROUND

Embodiments of the present disclosure relate to a thermoelectric couple and a device formed by electrically coupling a plurality of thermoelectric couples.

A thermoelectric couple or thermoelectric device can be used to generate electrical power or for heating or cooling. A thermoelectric couple includes an n-type thermoelectric leg electrically coupled by a contact to a p-type thermoelectric leg. The thermoelectric device may include a plurality of alternating n-type thermoelectric legs and p-type thermoelectric legs electrically connected across each leg in series.

The thermoelectric legs may be spaced along a first direction. In use, a temperature difference may be applied across the thermoelectric couple in a second direction that is different to, e.g. orthogonal to, the first direction. The temperature difference may be applied across a contact-thermoelectric couple boundary. In response to the temperature difference, a voltage is generated by the thermoelectric couple. This voltage can be used to drive a current through the thermoelectric couple. Alternatively, a current may be driven through the thermoelectric couple to produce a temperature difference across the device, which can be used to cool or heat a thermal load.

Thermal and electrical resistance between the contacts and the thermoelectric couple affects the power efficiency of the thermoelectric couple. By improving the thermal performance of the thermoelectric legs, the thermal efficiency of the thermoelectric couple can be increased. This increase in the thermal efficiency results in a higher power output of the thermoelectric couple for a given temperature difference across the thermoelectric couple.

To improve the thermal performance of the thermoelectric legs, the thermal conductivity of the thermoelectric legs may be decreased. Alternatively or additionally, the electrical conductivity of the thermoelectric legs may be increased. By increasing the electrical conductivity of the thermoelectric legs, the performance of the thermoelectric couple may be increased.

U.S. Pat. No. 7,999,172 describes a flexible thermoelectric couple and a manufacturing method thereof. The flexible thermoelectric couple comprises flexible substrates.

Korean patent, KR 1630715B1, describes an n-type element for a thermoelectric device comprising carbon nanotubes concentrated in spaces between glass bubbles.

### SUMMARY

A summary of aspects of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects and/or a combination of aspects that may not be set forth.

The performance Z_{T} of specific active materials suitable for use in thermoelectric couples, such as thermoelectric generators, may be represented by Equation 1:

$${Z}_{T} = \frac{{S}^{2} σ}{κ} T$$

In Equation 1, S is the Seebeck coefficient, a is the electrical conductivity, κ is the thermal conductivity and T is the temperature of operation. Therefore, increasing the electrical conductivity and/or the Seebeck coefficient will lead to improved performance Z_{T}. Furthermore, decreasing the thermal conductivity will lead to improved performance Z_{T}.

Ceramics or solid state alloys can have high thermal conductivity (of the order of around 1 to 3 watts per meter-Kelvin (W m⁻¹K⁻¹)), but are generally hard and brittle so problematic for incorporating in thermoelectric couples.

A binder containing n-type or p-type semiconductor distributed therein may have lower thermal conductivity than a bulk semiconductor material. However, there is a need for further reducing the thermal conductivity of materials for use in thermoelectric legs.

The present inventors have found that use of hollow microspheres in thermoelectric legs can reduce thermal conductivity, while maintaining good electrical conductivity and Seebeck coefficient.

According to some embodiments of the present disclosure, there is provided a thermoelectric device having one or more thermoelectric couples, each thermoelectric couple having an n-type thermoelectric leg and a p-type thermoelectric leg electrically coupled by a first electrical contact. At least one of the n-type and p-type thermoelectric legs contains a particulate semiconductor mixed with hollow microspheres. According to some embodiments of the present disclosure, the hollow microspheres may make up between 40% and 90% by volume of the thermoelectric leg. Even with volumes of the hollow microspheres in excess of 50%, 60%, 70% or 80%, it was found that the leg(s) had reduce thermal conductivity, but maintained good electrical conductivity and Seebeck coefficient.

In some embodiments the semiconductor particles are distributed in a binder.

In some embodiments, the particles are inorganic. In some embodiments, the n-type semiconductor is in particulate form and contains an alloy of bismuth, and tellurium or selenium. In some embodiments, the particles contain Bi₂Te₃, or Bi₂Se₃. In some embodiments, the particles contain Bi₂Te₃ doped with Se.

In some embodiments, the p-type semiconductor is in particulate form and contains an alloy of bismuth, tellurium and antimony. In some embodiments, the particles contain Bi_{1.5}Sb_{0.5}Te₃.

In some embodiments, the n-type semiconductor and the p-type semiconductor particles are spheroid.

In some embodiments, at least one of the n-type thermoelectric leg and the p-type thermoelectric leg contain or consist of hollow microspheres, spheroid semiconductor particles and a binder.

In some embodiments, at least one of the n-type thermoelectric leg and the p-type thermoelectric leg contains between 50% and 80% by volume hollow microspheres. In some embodiments, the hollow microspheres are glass microspheres. In some embodiments, the hollow microspheres have a diameter of 1-1000 μm. In some embodiments, the hollow microspheres have a diameter of 1-100 μm.

In some embodiments, a there is provided a thermoelectric device containing a plurality of electrically connected thermoelectric couples as described herein. Each thermoelectric couple may be electrically coupled to at least one adjacent thermoelectric couple by a second electrical contact between the thermoelectric couples.

According to some embodiments of the present disclosure there is provided a method for producing a thermoelectric device containing one or more thermoelectric couples as described herein, wherein formation of one or both of the n-type and p-type thermoelectric legs includes printing of an ink containing a semiconductor and hollow microspheres.

According to some embodiments of the present disclosure there is provided a composition comprising a plurality of spheroid n-type or p-type semiconducting particles, a plurality of hollow microspheres and a binder. The composition may form n-type and/or p-type thermoelectric legs of a thermoelectric device as described herein. The semiconducting particles, hollow microspheres and binder of the composition may be as described anywhere herein.

According to some embodiments, at least one of the n-type and p-type thermoelectric legs of a thermoelectric device may comprise the composition.

According to some embodiments, there is provided an ink in which the composition is dispersed in a liquid. According to some embodiments, the ink may be used to print a thermoelectric leg of a thermoelectric device.

### BRIEF DESCRIPTION OF DRAWINGS

The present disclosure is described in conjunction with the appended figures. It is emphasized that, in accordance with the standard practice in the industry, various features are not drawn to scale. In fact, the dimensions of the various features may be arbitrarily increased or reduced for clarity of discussion.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

FIG. 1 provides a schematic side view of a thermoelectric device, in accordance with some embodiments of the present disclosure.

FIG. 2 provides a cross section SEM of the composite material with 75% glass microspheres included.

FIG. 3 provides a top view SEM of the composite material with 75% glass microspheres included.

### DETAILED DESCRIPTION

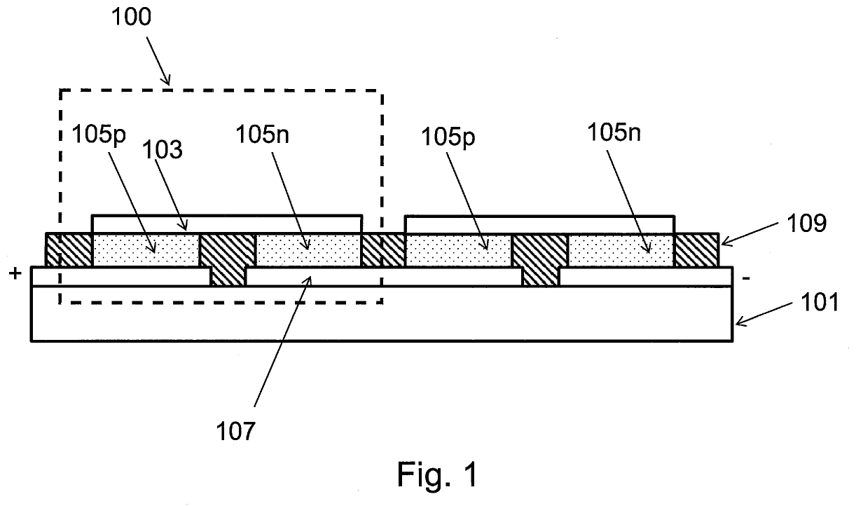

FIG. 1, which is not drawn to any scale, schematically illustrates a thermoelectric device according to some embodiments.

The thermoelectric device comprises at least one thermoelectric couple 100, the or each thermoelectric couple 100 comprising a p-type thermoelectric leg 105p and an n-type thermoelectric leg 105n, first ends of the thermoelectric legs 105p, 105n being electrically coupled by a first electrical contact 103.

For simplicity, FIG. 1 illustrates a device having only two thermoelectric couples however it will be appreciated that the thermoelectric device may comprise only one thermoelectric couple, or two or a larger number connected in an array. The thermoelectric couples may be connected to one another in series, parallel or a combination thereof.

In some embodiments, the thermoelectric device comprises a plurality of thermoelectric couples 100, wherein each thermoelectric couple 100 is electrically connected to at least one adjacent thermoelectric couple 100 by a second electrical contact 107. The second electrical contact 107 electrically connects a second end of one of a p-type and n-type thermoelectric leg of a thermoelectric couple 100 to a second end of the other of a p-type and n-type thermoelectric leg of an adjacent thermoelectric couple.

In some embodiments, the thermoelectric device comprises a plurality of thermoelectric couples connected in series. It will be understood that thermoelectric couples at the ends of the series connection are each connected to only one adjacent thermoelectric couple whereas every other thermoelectric couple is connected to two adjacent thermoelectric couples.

For the purpose of illustration, FIG. 1 illustrates a thermoelectric couple 100 electrically connected by a first contact 103, however it will be understood that any two adjacent, electrically connected n-type and p-type thermoelectric legs may form a thermoelectric couple as described herein, for example adjacent n-type and p-type thermoelectric legs which are electrically coupled by second electrical contact 107. Likewise, it will be understood that the first and second contacts and first and second ends of thermoelectric legs as described herein may be interchangeable.

The first and second electrical contacts 103 and 107 may each form a pattern of a plurality of conducting pads connecting the thermoelectric legs. In some embodiments, the first and second contacts are each in the form of a patterned layer defining a plurality of conductive pads.

In some embodiments, the first and second contacts may each independently consist of a single conductive layer or two or more conductive layers. The or each conductive layer may consist of a single conductive material or may comprise two or more materials. In some embodiments, the conductive materials for forming the conductive layers are preferably selected from metals and conductive metal compounds, for example conductive metal oxides. Exemplary metals are copper, aluminium and gold. In some embodiments, the first and second contacts optionally each independently have a thickness in the range of about 1-10 microns.

In some embodiments, the thermoelectric device is supported on a first substrate 101. The substrate may consist of a single layer. The substrate or may comprise two or more layers of different materials. In some embodiments, the thermoelectric device may be a flexible device supported on a flexible substrate 101.

In some embodiments a thermoelectric device may have a bend radius of 30 mm or less, optionally 20 mm or less. In some embodiments, the bend radius may be at least 5 mm or at least 10 mm. In some embodiments, the thickness of the thermoelectric couples of the thermoelectric device is preferably in the range of about 50-500 microns, optionally 50-300 microns.

The p-type semiconductor or n-type semiconductor of the n-type thermoelectric leg or the p-type thermoelectric leg may be selected from known thermoelectric materials as disclosed in, for example, J. Mater. Chem. C, 2015, 3, 10362 and Chem. Soc. Rev., 2016, 45, 6147-6164, the contents of which are incorporated herein by reference.

In some embodiments, at least one of the n-type semiconductor and the p-type semiconductor is in particulate form.

In some embodiments the n-type semiconductor is in particulate form.

In some embodiments the p-type semiconductor is in particulate form.

Semiconducting particles described herein may have a D50 diameter of between 0.1 and 100 μm. By “D50 diameter” of particles as used herein is meant a mass mean diameter of the particles, i.e. a diameter at which 50% of the mass of a sample of the particles consists of particles having a diameter no greater than the D50 diameter, the other 50% having a diameter greater than the D50 diameter.

In some embodiments, the n-type semiconductor particles are spheroid. In some embodiments, the p-type semiconductor particles are spheroid. Spheroid particles as described herein may have an average largest dimension to smallest dimension ratio (e.g. a length to width ratio) that is less than 2:1. The ratio may be determined by measuring largest and smallest dimensions from an image of a plurality of particles in a sample of the particles.

In some embodiments, the p-type thermoelectric leg does not comprise carbon nanotubes.

In some embodiments the particles are distributed in a binder. In some embodiments the binder may be a polymeric binder. In some embodiments, the polymeric binder may be a conjugated or non-conjugated polymer.

In some embodiments, the n-type thermoelectric leg comprises or consists of hollow microspheres, spheroid n-type semiconductor particles and a binder. In some embodiments, the p-type thermoelectric leg comprises or consists of hollow microspheres, spheroid p-type semiconductor particles and a binder.

Exemplary non-conjugated binders include, without limitation, polyvinylpyrrolidone, PVDF, polyacrylates, preferably PMMA, and polystyrene, epoxys, and silicones e.g. PDMS.

Exemplary conjugated polymer binders include, without limitation, polymers containing thiophene repeat units, e.g. P(NDI2OD-T2), polymers containing fluorene repeat units, such as for example poly[(9,9-di-n-octylfluorenyl-2,7-diyl)-alt-(benzo[2,1,3]thiadiazol-4,8-diyl)] (F8BT), polyphenylenevinylenes, e.g. benzodifurandione-based PPV (BDPPV) and PEDOT doped with a suitable polyanion, e.g. PSS.

The binder may comprise may contain only one polymeric binder or may contain more than one polymeric binder. In some embodiments, the particles are inorganic.

In some embodiments, the n-type semiconductor is in particulate form and comprises or consists of an alloy of bismuth (Bi), and tellurium (Te) or selenium (Se). In some embodiments, the particles comprise Bi₂Te₃, and/or Bi₂Se₃. In some embodiments, the particles are doped with a dopant. In some embodiments, the particles comprise Bi₂Te₃ doped with Se. Examples of first dopants include selenium (Se), bismuth (Bi), sulfur (S), iodine (I) and/or the like. In some embodiments, the concentration of the first dopant may be between 1% and 10%. In some embodiments, the particles are doped with at least 1 weight % of the dopant, optionally at least 5 or 10 wt % of the dopant agent.

In some embodiments, the p-type semiconductor is in particulate form and may comprise or consist of an alloy of bismuth (Bi), tellurium (Te), and antimony (Sb), for example Bi_{1.5}Sb_{0.5}Te₃, and/or an additional second dopant. In some embodiments, the p-type semiconducting particles may comprise or consist of an alloy of lead (Pb) and tellurium (Te), an alloy of tin (Sn) and selenium (Se), or an alloy of silicon (Si) and germanium (Ge), and/or optionally an additional second dopant. Examples of second dopants include tellurium (Te), selenium (Se), sulfur (S), arsenic (As), antimony (Sb), phosphorus (P), bismuth (Bi) and the halogens. The concentration of second dopant may be between 1% and 10%. In some embodiments, the particles are doped with at least 1 weight % of the dopant, optionally at least 5 or 10 wt % of the dopant agent.

In some embodiments, at least one of the n-type thermoelectric leg and the p-type thermoelectric leg comprises between 50% and 80% by volume hollow microspheres.

In some embodiments, at least one of the n-type thermoelectric leg and the p-type thermoelectric leg comprises between 50% and 75% by volume hollow microspheres.

In some embodiments, at least one of the n-type thermoelectric leg and the p-type thermoelectric leg comprises between 55% and 70% by volume hollow microspheres.

In some embodiments, the hollow microspheres comprise glass or plastic, e.g. polyethylene, PMMA, PVC or aluminosilicate. In some embodiments, the hollow microspheres are glass microspheres. In some embodiments, the hollow microspheres have a D50 diameter of 10-1000 μm. In some embodiments, the hollow microspheres have a D50 diameter of 10-100 μm.

In some embodiments, the n-type thermoelectric leg and the p-type thermoelectric leg are electrically connected in series.

Manufacture of Flexible Thermoelectric Couple

According to some embodiments of the present disclosure there is provided a method for producing a thermoelectric device as described herein, the method comprising the step of printing at least one of the n-type and p-type thermoelectric legs onto a surface wherein the or each printed thermoelectric leg comprises particulate semiconductor and between 40% and 90% by volume hollow microspheres. The surface may be a contact for electrically coupling the first and second thermoelectric legs.

To form a thermoelectric device comprising a plurality of electrically connected thermoelectric couples, the n-type and p-type thermoelectric legs may be formed on a first conductive layer comprising a plurality of contact pads wherein one n-type and one p-type thermoelectric leg is formed on each contact pad to form a plurality of thermoelectric couples which are not electrically connected to one another. Adjacent thermoelectric couples may then be electrically connected by providing electrical contacts therebetween.

Contacts between thermoelectric couples may be formed by any suitable deposition technique including, without limitation, evaporation and sputtering. In other embodiments, a second conductive layer comprising a plurality of conducting pads may be brought into contact with the unconnected thermocouples.

In some embodiments, in operation as a thermoelectric generator, the first or second contact is brought into proximity with a surface having a temperature higher than the environmental temperature. In some embodiments, the first or second contacts are electrically connected to a load.

In some embodiments, in operation as a thermoelectric cooler, the first or second contact is brought into proximity with a surface to be cooled and a voltage is applied to the device.

Compositions for Forming a Thermoelectric Leg

In some embodiments, a composition for forming a thermoelectric leg may comprise hollow microspheres and either a particulate n-type semiconductor or a particulate p-type semiconductor. In some embodiments, the composition may be deposited by any suitable technique, and preferably by deposition of an ink comprising the components of the composition dissolved or dispersed in one or more solvents. It will be understood that hollow microspheres and semiconductor particles are dispersed in the ink. A binder may be dissolved or dispersed in the ink, preferably dissolved.

In some embodiments, a thermoelectric leg formed by deposition of an ink onto a contact may have higher contact resistance than a thermoelectric leg formed by another process, for example evaporation. Accordingly, an ability to tune the conductivity of a thermoelectric leg formed from an ink may be particularly advantageous.

Suitable techniques for depositing an ink are coating or printing methods including, without limitation, roll-coating, spray coating, doctor blade coating, slit coating, ink jet printing, screen printing, dispense printing, gravure printing and flexographic printing.

In dispense printing, each thermoelectric leg is formed by depositing a continuous flow of ink from a nozzle positioned above the first electrode. It will be understood that no ink is dispensed in regions between each thermoelectric leg.

In some embodiments, the solvent or solvents for an ink as described herein may comprise or consist of one or more polar aprotic solvents such as N-methylpyrrolidone; dimethylformamide; propylene carbonate; and dimethylsulfoxide; one or more polar, protic solvents such as water or C₁₋₆ alcohols; benzene substituted with one or more C₁₋₁₀ alkyl or alkoxy groups, e.g. anisole; and ketones, e.g. methyl isobutyl ketone.

In some embodiments, ink formulations preferably further comprise a polymeric binder. The binder may make layers formed from the formulation more resilient and less likely to crack than films in which no binder is present. The binder may be the same as described in relation to the thermoelectric couple above.

### Examples

Thermoelectric Properties

The properties of a composition suitable for forming thermoelectric legs without glass bubbles (Comparative Composition 1) was compared to compositions containing about 50% and about 75% by volume of glass bubbles (Examples Materials 1 and 2 respectively).

Compositions were prepared by manually mixing 67 wt % of a p-type powder semiconductor Bi_{1.5}Sb_{0.5}Te₃ doped with 8% Te, 15 wt % of an epoxy binder and 18 wt % of a solvent mixture of 70:30 v/v methyl isobutyl ketone:anisole, followed by addition of glass microspheres (3M glass bubbles S22, 50^{th} centile size 35 microns). The compositions were manually deposited by pipette onto a glass substrate and dried 250° C. for 3 hours on a hotplate.

The electrical conductivity of each of the comparative materials and example materials was measured in a glove-box by connecting the samples to a Keithley 2400 Sourcemeter and making 4-point measurements. In particular, the resistance was measured for gaps of 1, 2, 3 and 4 mm in a TLM (Transmission Line Model) type test. Thickness of the samples was measured by scratching a channel in the material and using a surface profiler to measure the step height. The lateral conductivity was then calculated from the regression of resistance measurements and the measured thickness in accordance with the following equation (I):

R=L/(σTW) (I)

with R denoting the resistance, L the electrode spacing, T the layer thickness, W the sample width and σ the conductivity of the sample.

The Seebeck coefficient of each of the comparative materials and example materials was measured by placing the sample on two Peltier elements to generate a temperature gradient across the sample. Contacts were made to the samples to measure the generated voltage and the resistance across samples. This data was logged as the temperature gradient (ΔT) is driven between 0° C. and 10° C. The temperature was measured when ΔT=0° C. using thermocouples placed on the substrate surface. Using the logged resistance data, a measurement of substrate temperature, and thus ΔT, was made, which was referenced to the thermocouple temperature. The generated voltage was then plotted against the temperature gradient to derive the Seebeck coefficient S from the slope according to the following equation (II):

V=SΔT (II)

The thermal conductivity of each of the comparative materials and example materials was calculated using Maxwell's model of effective thermal conductivity in composite systems (Equation 2).

$$\frac{{K}_{e f f}}{{K}_{m}} = 1 + \frac{3 ϕ}{( \frac{{K}_{1} + 2 {K}_{m}}{{K}_{1} - {K}_{m}} ) - ϕ} \qquad Equation 2$$

In Equation 2, K_{eff} is the effective thermal conductivity of the composite, K₁ is the thermal conductivity of the additive, Kₘ, the bulk medium and ϕ is the volume fraction of the additive in the medium.

The calculated performance of each of the comparative materials and example materials was calculated using Equation 1.

$${Z}_{T} = \frac{{S}^{2} σ}{κ} T$$

In Equation 1, S is the Seebeck coefficient, a is the electrical conductivity, κ is the thermal conductivity and T is the temperature of operation. Experiments were carried out at 25° C.

TABLE 1

| | Micro- | Seebeck | | κ/ | Z_{T} |
|---|---|---|---|---|---|
| | sphere/ | coefficient/ | σ/ | W(mK⁻¹) | (300K) |
| Composition | % v/v | μVK⁻¹ | Scm⁻¹ | (Calculated) | (calc.) |
| Comparative | 0 | 267 | 14 | 0.24 | 0.12 |
| 1 | | | | | |
| Example 1 | 50 | 260 | 14 | 0.14 | 0.20 |
| Example 2 | 75 | 264 | 14 | 0.1 | 0.29 |

As shown in Table 1, Example Materials 1 and 2 exhibit lower thermal conductivity whilst retaining excellent electrical conductivity relative to Comparative Materials 1 and 2. Furthermore, Example Materials 1 and 2 also exhibit excellent Seebeck coefficient values whilst maintaining high electrical conductivity. As such, compositions containing hollow microspheres exhibit dramatically improved Z_{T}.

Scanning Electron Micrograph Image

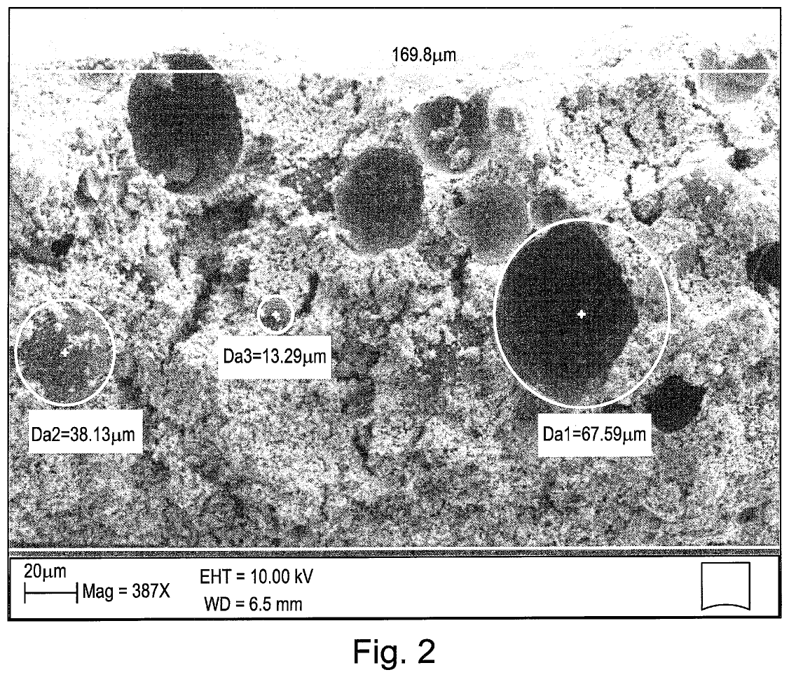

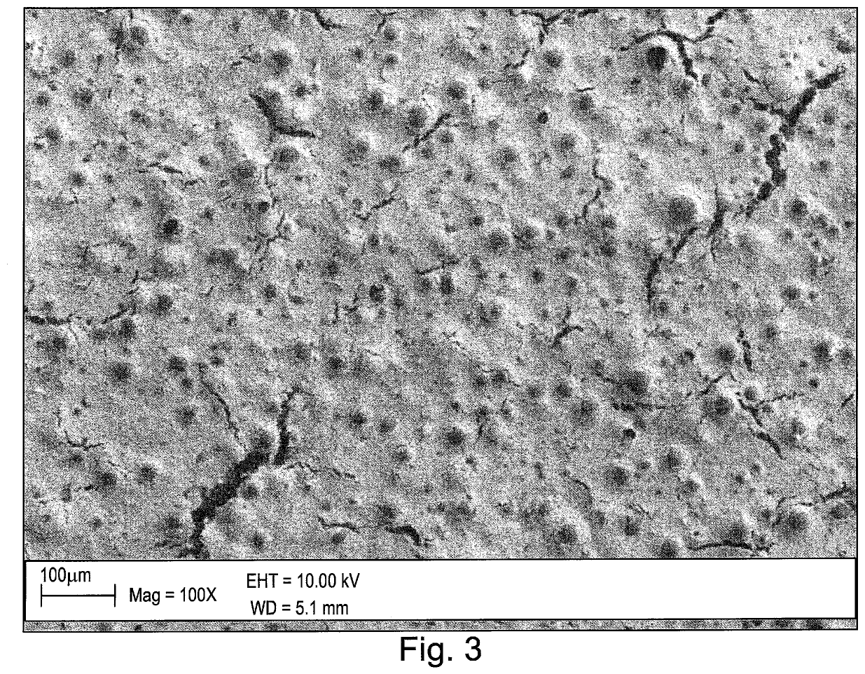

Referring to FIGS. 2 and 3, scanning electron micrograph (SEM) images of a cross section and top view, respectively, of the thermoelectric leg of Example 2 is shown.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” As used herein, the terms “connected,” “coupled,” or any variant thereof means any connection or coupling, either direct or indirect, between two or more elements; the coupling or connection between the elements can be physical, logical, electromagnetic, or a combination thereof. Additionally, the words “herein,” “above,” “below,” and words of similar import, when used in this application, refer to this application as a whole and not to any particular portions of this application. Where the context permits, words in the Detailed Description using the singular or plural number may also include the plural or singular number respectively. The word “or,” in reference to a list of two or more items, covers all of the following interpretations of the word: any of the items in the list, all of the items in the list, and any combination of the items in the list.

The teachings of the technology provided herein can be applied to other systems, not necessarily the system described below. The elements and acts of the various examples described below can be combined to provide further implementations of the technology. Some alternative implementations of the technology may include not only additional elements to those implementations noted below, but also may include fewer elements.

These and other changes can be made to the technology in light of the following detailed description. While the description describes certain examples of the technology, and describes the best mode contemplated, no matter how detailed the description appears, the technology can be practiced in many ways. Details of the system may vary considerably in its specific implementation, while still being encompassed by the technology disclosed herein. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the Detailed Description section explicitly defines such terms. Accordingly, the actual scope of the technology encompasses not only the disclosed examples, but also all equivalent ways of practicing or implementing the technology under the claims.

To reduce the number of claims, certain aspects of the technology are presented below in certain claim forms, but the applicant contemplates the various aspects of the technology in any number of claim forms. For example, while some aspect of the technology may be recited as a computer-readable medium claim, other aspects may likewise be embodied as a computer-readable medium claim, or in other forms, such as being embodied in a means-plus-function claim.

In the description above, for the purposes of explanation, numerous specific details are set forth in order to provide a thorough understanding of implementations of the disclosed technology. It will be apparent, however, to one skilled in the art that embodiments of the disclosed technology may be practiced without some of these specific details.

1. A thermoelectric device, comprising:
a thermoelectric couple comprising an n-type thermoelectric leg comprising an n-type semiconductor, a p-type thermoelectric leg comprising a p-type semiconductor and a first electrical contact electrically coupling a first end of the n-type thermoelectric leg and a first end of the p-type thermoelectric leg, wherein at least one of the n-type thermoelectric leg and the p-type thermoelectric leg comprises a semiconductor in particulate form, between about 40% and 90% by volume hollow microspheres, and a binder selected from polyvinylpyrrolidone, PVDF, polyacrylates, polystyrene, and epoxys.

2. (canceled)

3. The thermoelectric device according to claim 1 wherein the semiconducting particles are inorganic.

4. The thermoelectric device according to claim 1, wherein the n-type semiconductor is in particulate form.

5. The thermoelectric device according to claim 4, wherein the n-type semiconductor comprises an alloy of and tellurium or bismuth and selenium.

6. The thermoelectric device according to claim 5, wherein the n-type semiconductor comprises Bi₂Te₃, or Bi₂Se₃.

7. The thermoelectric device according to claim 6, wherein the n-type semiconductor comprises Bi₂Te₃ doped with Se

8. The thermoelectric device according to claim 1, wherein the p-type semiconductor is in particulate form.

9. The thermoelectric device according to claim 8, wherein the p-type semiconductor comprises an alloy of bismuth, tellurium and antimony.

10. (canceled)

11. The thermoelectric device according to claim 1, wherein the thermoelectric leg comprising the hollow microspheres is between about 50% and 80% by volume hollow microspheres.

12. The thermoelectric device according to claim 1, wherein the hollow microspheres comprise glass microspheres.

13. The thermoelectric device according to claim 1, wherein the hollow microspheres have a D50 value of about 10-1000 μm.

14. The thermoelectric device according to claim 13, wherein the hollow microspheres have a D50 value of about 10-100 μm.

15. A thermoelectric device, comprising a plurality of electrically connected thermoelectric couples according to any one of the preceding claims.

16. A thermoelectric device according to claim 15, wherein, for each of the thermoelectric couples, at least one of a second end of the n-type thermoelectric leg and a second end of the p-type thermoelectric leg is electrically coupled by an electrical contact to an adjacent thermoelectric couple.

17. A method for producing a thermoelectric device according to claim 1, wherein formation of at least one of the n-type and p-type thermoelectric legs comprises printing an ink comprising the particulate semiconductor and the hollow microspheres.

18. A thermoelectric device manufactured by the method according to claim 17.

19. A composition configured for use in a leg of a thermoelectric device, comprising a plurality of spheroid n-type or p-type semiconducting particles, a plurality of hollow microspheres and a binder selected from polyvinylpyrrolidone, PVDF, polyacrylates, polystyrene, and epoxys.

20. The composition of claim 19, wherein the plurality of hollow microspheres comprise greater than 50%, 60%, 70% or 80% by volume of the composition.

21. A thermoelectric device, comprising:
a thermoelectric couple comprising an n-type thermoelectric leg, a p-type thermoelectric leg and a first electrical contact electrically coupling a first end of the n-type thermoelectric leg and a first end of the p-type thermoelectric leg, wherein at least one of the n-type and p-type thermoelectric legs comprises a composition according to claim 19.

22. An ink, comprising a composition according to claim 19 dispersed in a liquid.
